(19) United States
(12) Patent Application Publication
(10) Pub. No.: US 2017/0062240 A1
(43) Pub. Date: Mar. 2, 2017

(54) METHOD FOR MANUFACTURING A WAFER LEVEL PACKAGE

(71) Applicant: Inotera Memories, Inc., Taoyuan City (TW)

(72) Inventors: Tieh-Chiang Wu, Taoyuan City (TW); Shing-Yih Shih, New Taipei City (TW)

(21) Appl. No.: 14/835,687

(22) Filed: Aug. 25, 2015

(51) Int. Cl. H01L 21/48; H01L 23/00; H01L 21/768; H01L 23/498; H01L 21/56; H01L 21/02

(52) U.S. Cl. CPC H01L 21/4853; H01L 21/486; H01L 21/565; H01L 21/02164; H01L 21/0217; H01L 21/76831; H01L 23/49816; H01L 24/81; H01L 21/7684; H01L 2224/81192; H01L 2924/15738; H01L 2924/01014

(57) ABSTRACT

A method for fabricating a wafer level package is disclosed. A substrate having a top surface and a bottom surface is provided. A first dielectric layer is formed on the top surface. A redistribution layer (RDL) is formed on the first dielectric layer. The RDL comprises at least a second dielectric layer and at least a metal layer in the second dielectric layer. A first passivation layer is formed on the RDL. Bumps are formed in the first passivation layer. A chip is mounted on the RDL. The chip is electrically connected to the metal layer through the bumps. A molding compound is applied on the first passivation layer and around the chip. The bottom surface of the substrate is grinded until a remaining thickness of the substrate is reached. A plurality of through substrate vias is formed in the substrate.

### BACKGROUND OF THE INVENTION

1. Field of the Invention

The present invention relates generally to the field of semiconductor packaging, and more particularly to a method for manufacturing a wafer level package (WLP).

2. Description of the Prior Art

With recent advancements in the semiconductor manufacturing technology microelectronic components are becoming smaller and circuitry within such components is becoming increasingly dense. To reduce the dimensions of such components, the structures by which these components are packages and assembled with circuit boards must become more compact.

As known in the art, Chip on Wafer on Substrate (CoWoS) typically uses Through Silicon Via (TSV) technology to integrate multiple chips into a 2.5D or 3D IC device. This architecture provides higher density interconnects, decreases global interconnect length, and lightens associated RC loading resulting in enhanced performance and reduced power consumption on a smaller form factor. The chips may be interconnected through a redistribution layer (RDL) that is typically formed on a silicon interposer or TSV interposer. The TSV interposer is costly because fabricating the interposer substrate with TSVs is a complex process.

The RDL is typically defined by the addition of metal and dielectric layers onto the surface of the wafer to re-route the I/O layout into a looser pitch footprint. Such redistribution requires thin film polymers such as BCB, PI or other organic polymers and metallization such as Al or Cu to reroute the peripheral pads to an area array configuration.

In wafer level packaging, the wafer and the dies mounted on the wafer are typically covered with a relatively thick layer of the molding compound. The thick layer of the molding compound results in increased warping of the packaging due to coefficient of thermal expansion (CTE) mismatch, and the thickness of the packaging. It is known that wafer warpage continues to be a concern.

Warpage can prevent successful assembly of a die-to-wafer stack because of the inability to maintain the coupling of the die and wafer. Warpage issue is serious especially in a large sized wafer, and has raised an obstacle to a wafer level semiconductor packaging process that requires fine-pitch RDL process. Therefore, there remains a need in the art for an improved method of manufacturing wafer level packages.

### SUMMARY OF THE INVENTION

It is one object of the invention to provide an improved method for fabricating a wafer level package (WLP). The through silicon via or through substrate via (TSV) is fabricated after die attachment and wafer level molding (a “TSV-last” process) so as to reduce cost and alleviate post-molding warpage.

In one aspect of the invention, a method for fabricating a wafer level package is disclosed. A substrate having a top surface and a bottom surface is provided. A first dielectric layer is formed on the top surface. A redistribution layer (RDL) is formed on the first dielectric layer. The RDL comprises at least a second dielectric layer and at least a metal layer in the second dielectric layer. A first passivation layer is formed on the RDL. Bumps are formed in the first passivation layer. A chip is mounted on the RDL. The chip is electrically connected to the metal layer through the bumps. A molding compound is applied on the first passivation layer and around the chip. The bottom surface of the substrate is grinded until a remaining thickness of the substrate is reached. A plurality of through substrate vias is formed in the substrate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

The accompanying drawings are included to provide a further understanding of the embodiments, and are incorporated in and constitute apart of this specification. The drawings illustrate some of the embodiments and, together with the description, serve to explain their principles. In the drawings:

FIG. 1 to FIG. 10 are schematic diagrams showing an exemplary method for fabricating a wafer level package (WLP) according to one embodiment of the invention, wherein,

### DETAILED DESCRIPTION

In the following detailed description of the invention, reference is made to the accompanying drawings, which form a part hereof, and in which is shown, by way of illustration, specific embodiments in which the invention may be practiced. These embodiments are described in sufficient detail to enable those skilled in the art to practice the invention. Other embodiments maybe utilized and structural changes may be made without departing from the scope of the present invention.

The following detailed description is, therefore, not to be taken in a limiting sense, and the scope of the present invention is defined only by the appended claims, along with the full scope of equivalents to which such claims are entitled. One or more implementations of the present invention will now be described with reference to the attached drawings, wherein like reference numerals are used to refer to like elements throughout, and wherein the illustrated structures are not necessarily drawn to scale.

The present invention pertains to a “TSV-last” process for making a wafer level package (WLP). The remaining thickness of the substrate maybe designed to efficiently control the package warpage. The through silicon via or through substrate via (TSV) is fabricated after die attachment and wafer level molding.

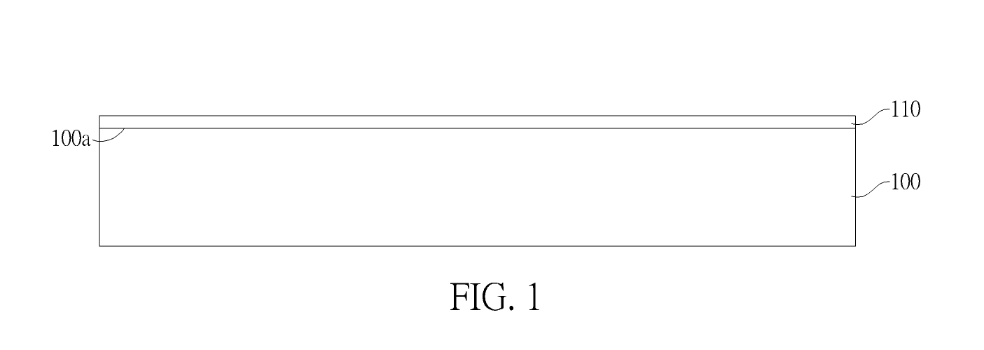

Please refer to FIG. 1 to FIG. 10. FIG. 1 to FIG. 10 are schematic diagrams showing an exemplary method for fabricating a wafer level package (WLP) according to one embodiment of the invention. As shown in FIG. 1, a substrate 100 is provided. For example, the substrate 100 may comprise a silicon substrate, but not limited thereto. At least a dielectric layer 110 is then formed on a top surface 100a of the substrate 100. The dielectric layer 110 may comprise silicon oxide, but not limited thereto.

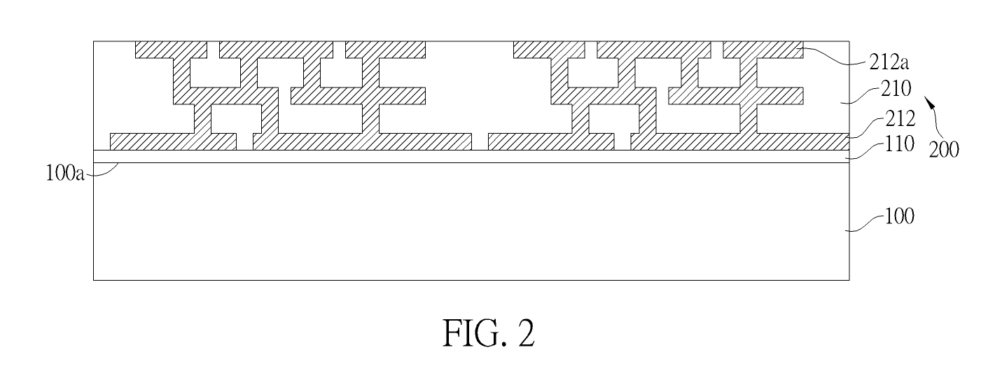

As shown in FIG. 2, a redistribution layer (RDL) 200 is formed on the dielectric layer 110. The RDL 200 may comprise at least one dielectric layer 210 and at least one metal layer 212. The dielectric layer 210 may comprise silicon nitride, silicon oxide or the like, but not limited thereto. The metal layer 212 may comprise aluminum, copper, tungsten, titanium, titanium nitride, or the like. According to the illustrated embodiment, the metal layer 212 may comprise a plurality of bump pads 212a exposed from a top surface of the dielectric layer 210. The bump pads 212a are disposed within a chip mounting area.

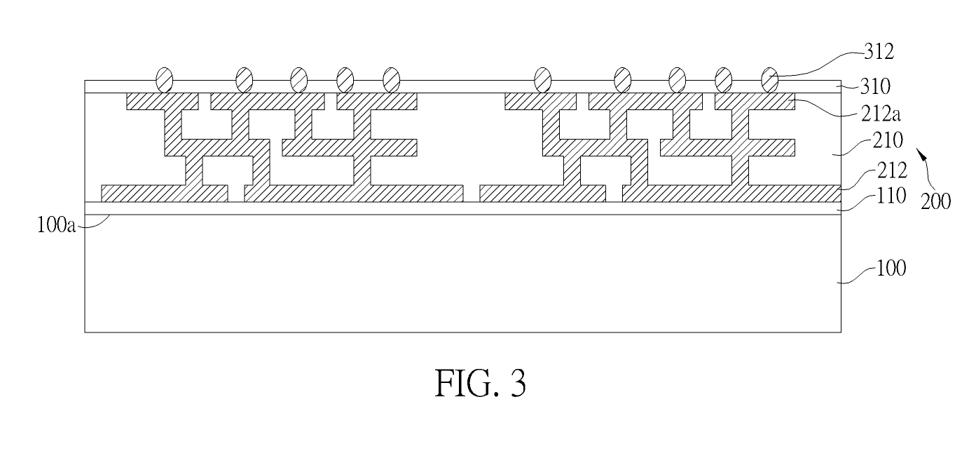

As shown in FIG. 3, a passivation layer or a dielectric layer 310 may be formed on the RDL 200. A plurality of bumps 312 such as micro-bumps may be formed on the RDL 200 for further connections. The bumps 312 may be directly formed on respective bump pads 212a in the metal layer 212.

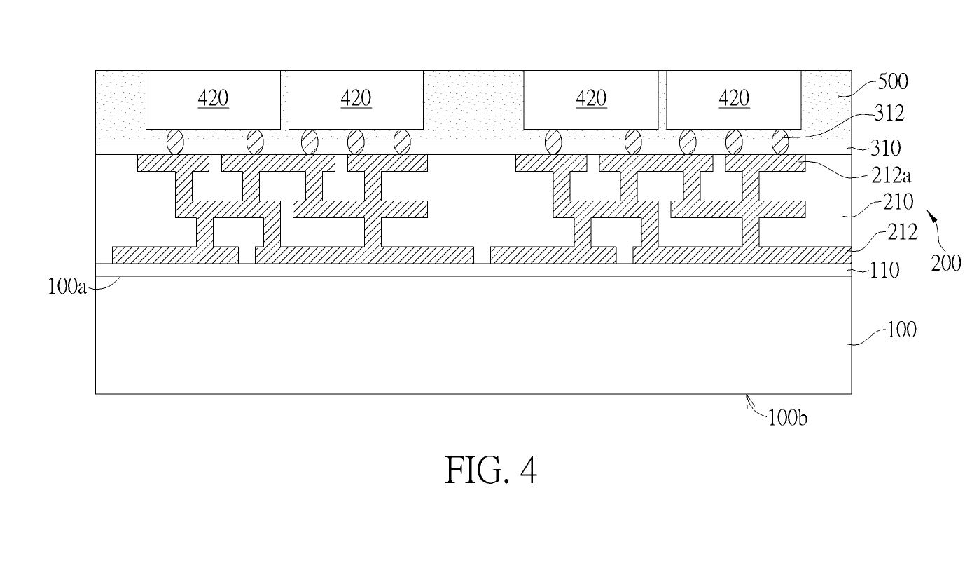

As shown in FIG. 4, after the formation of the bumps 312, individual flip-chips or dies 420 with their active sides facing down toward the RDL 200 are then mounted on the RDL 200 through the bumps 312 to thereby forming a stacked chip-to-wafer (C2W) construction. These individual flip-chips or dies 420 are active integrated circuit chips with certain functions, for example, GPU (graphic processing unit), CPU (central processing unit), memory chips, etc.

After the die-bonding process, a molding compound 500 is applied. The molding compound 500 covers the attached chips 420 and the top surface of the RDL 200. The molding compound 500 may be subjected to a curing process. The mold compound 500 may comprise a mixture of epoxy and silica fillers, but not limited thereto. Subsequently, a top portion of the molding compound 500 maybe polished away to expose a top surfaces of the chips 420.

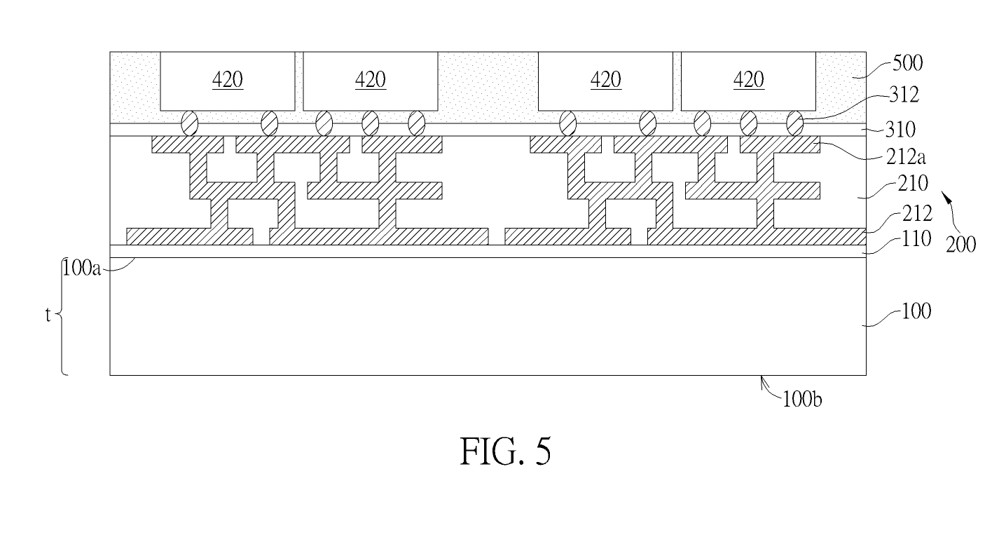

As shown in FIG. 5, after the molding process, a grinding process is performed to polish the bottom surface 100b of the substrate 100, to thereby reduce the thickness of the substrate 100. The remaining thickness t may depend on the degree of warpage or other design requirements. For example, the remaining thickness t may range between 0 and 120 micrometers. It is advantageous to use the present invention because the remaining thickness t may be designed to control the warpage depending on the sizes (or dimensions) of the chip packages.

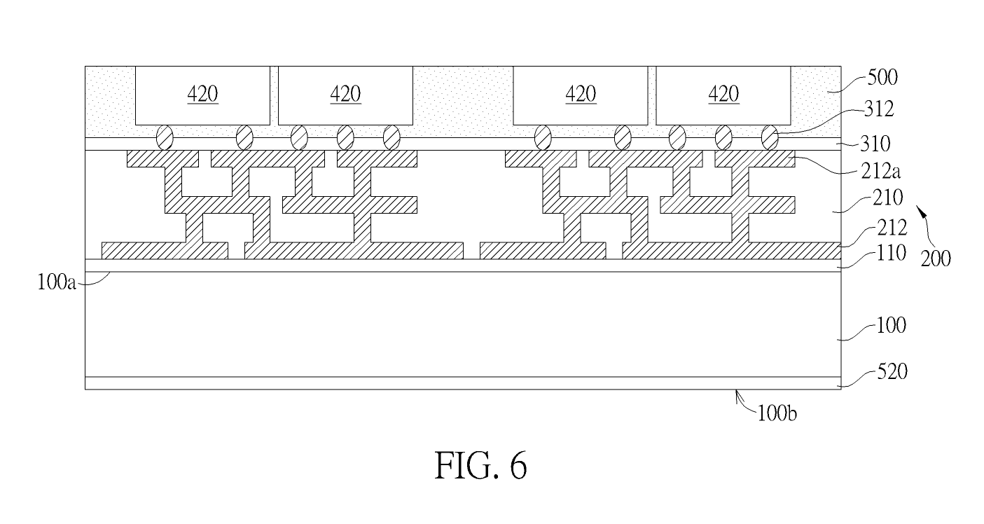

As shown in FIG. 6, a dielectric layer 520 such as a silicon oxide layer is deposited on the bottom surface 100b of the substrate 100.

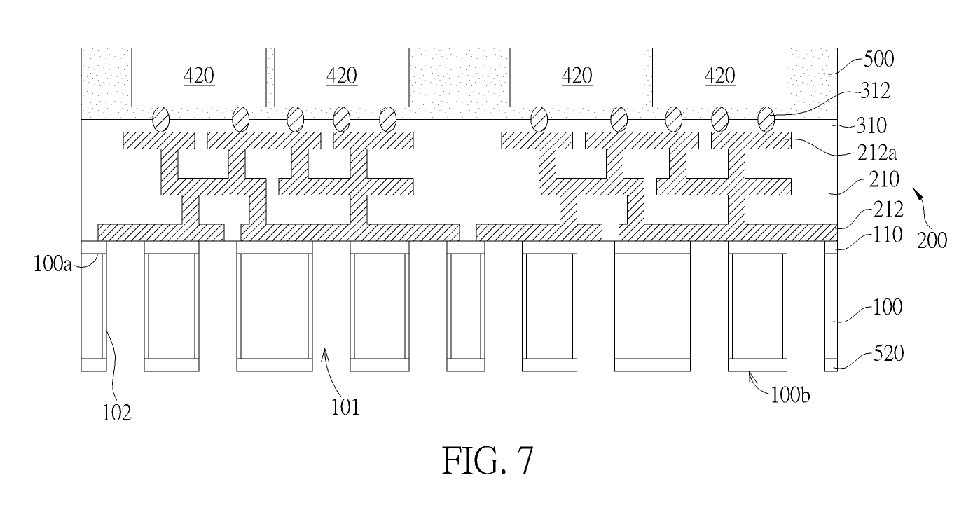

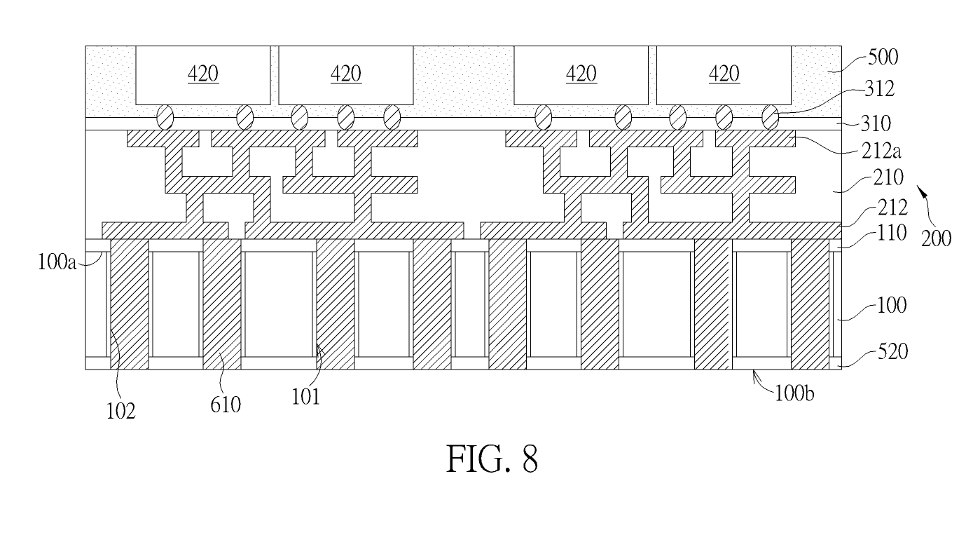

As shown in FIG. 7 and FIG. 8, a through substrate via (TSV) process is then performed. First, a plurality of through holes 101 is formed in the substrate 100. For example, the through holes 101 maybe formed by using conventional lithographic processes and etching processes. An oxide liner 102 may be formed on the sidewalls of the through holes 101, as shown in FIG. 7. Subsequently, the through holes 101 are filled with conductive material such as metal, and then polished to remove excess metal outside the through holes 101, thereby forming TSVs 610, as shown in FIG. 8.

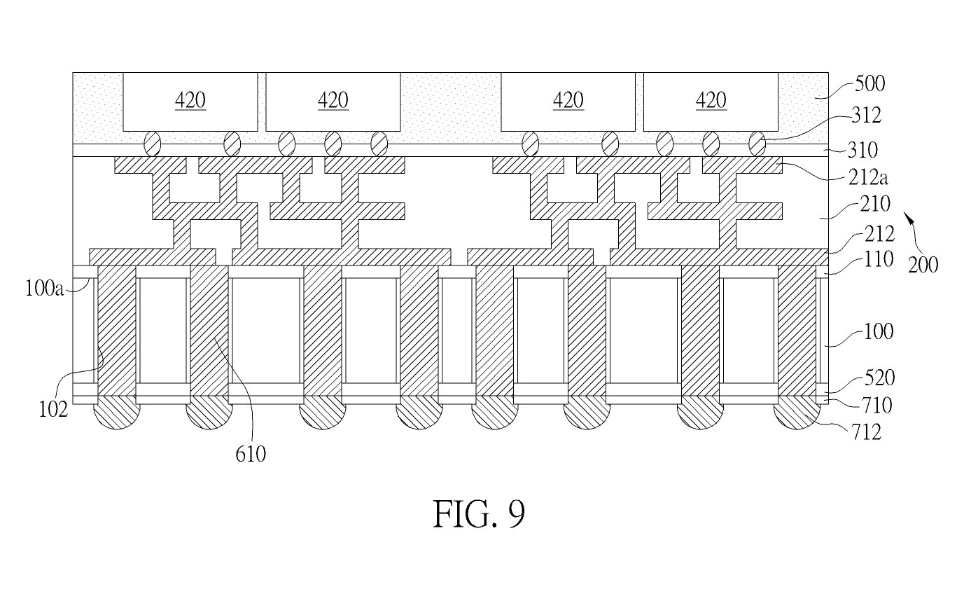

As shown in FIG. 9, a passivation layer 710 may be formed on the bottom surface 100b of the substrate 100. For example, the passivation layer 710 may comprise organic materials such as polyimide (PI) or inorganic materials such as silicon nitride, silicon oxide or the like. A plurality of solder balls 712 is then formed on the respective TSVs 610. For example, a conventional lithographic process and an etching process may be used to form a plurality of openings in the passivation layer 710. Solder balls 712 may be disposed in the openings and then reflowed.

It is understood that the structure at the bottom surface 100b of the substrate 100 as depicted in FIG. 9 is for illustration purposes only. The solder balls 712 may not be directly formed on the bottom end of each of the TSVs 610. In another embodiment, for example, a backside RDL (not shown) may be formed on the passivation layer 710 for further connection. The backside RDL on the passivation layer 710 may comprise one metal layer or multiple metal layers. The solder balls 712 may be placed on the metal pads defined in the backside RDL. In addition, the RDL on the bottom surface 100b of the substrate 100 may be formed concurrently with the TSVs 610 by using copper damascene process.

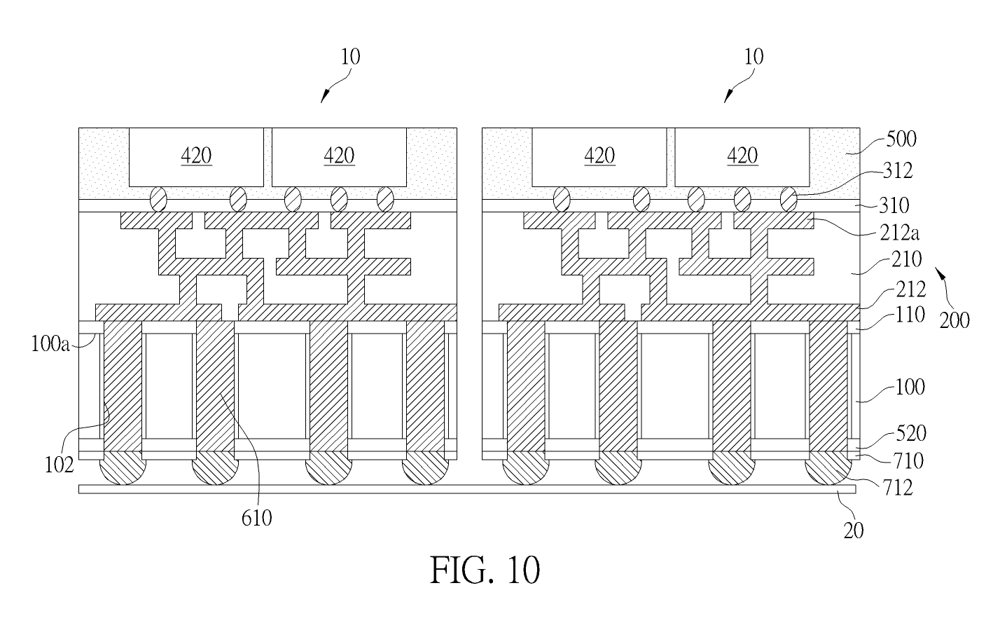

As shown in FIG. 10, a dicing process is performed to separate individual wafer level packages 10 from one another. During the dicing process, a dicing tape 20 may be used as a carrier.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating a wafer level package, comprising:
providing a substrate having a top surface and a bottom surface;
forming a first dielectric layer on the top surface;
forming a redistribution layer (RDL) on the first dielectric layer, wherein the RDL comprises at least a second dielectric layer and at least a metal layer in the second dielectric layer;
forming a first passivation layer on the RDL;
forming bumps in the first passivation layer;
mounting a chip on the RDL, wherein the chip is electrically connected to the metal layer through the bumps;
forming a molding compound on the first passivation layer and around the chip;
after forming the molding compound to surround the chip, grinding the bottom surface of the substrate until a remaining thickness of the substrate is reached; and
after grinding the bottom surface of the substrate until the remaining thickness of the substrate is reached, forming a plurality of through substrate vias in the substrate.

2. The method for fabricating a wafer level package according to claim 1, wherein the remaining thickness of the substrate is determined depending on degree of warpage and size of the wafer level package.

3. The method for fabricating a wafer level package according to claim 1, wherein the substrate is a silicon substrate.

4. The method for fabricating a wafer level package according to claim 1, wherein the first dielectric layer comprises silicon oxide.

5. The method for fabricating a wafer level package according to claim 1, wherein the second dielectric layer comprises silicon nitride or silicon oxide.

6. The method for fabricating a wafer level package according to claim 1, wherein said forming a plurality of through substrate vias in the substrate further comprises:
forming a third dielectric layer on the bottom surface of the substrate;
forming through holes in the substrate and the third dielectric layer;
forming an oxide liner on the sidewalls of the through holes;
filling the through holes with a conductive material; and
polishing the conductive material.

7. The method for fabricating a wafer level package according to claim 1 further comprising:
forming a second passivation layer on the bottom surface of the substrate; and
forming solder balls in the second passivation layer to electrically connect with the through substrate vias.
